(19) United States
(12) Patent Application Publication
(10) Pub. No.: US 2005/0241584 A1
(43) Pub. Date: Nov. 3, 2005

(54) Ceramics heater for semiconductor production system

(75) Inventors: Yoshifumi Kachi, Itami-shi (JP); Akira Kuibira, Itami-shi (JP); Hirohiko Nakata, Itami-shi (JP)

Correspondence Address: JUDGE PATENT FIRM;RIVIERE SHUKUGAWA 3RD FL., 3-1 WAKAMATSU-CHO, NISHINOMIYA-SHI, HYOGO, 662-0035, JP

(73) Assignee: Sumitomo Electric Industries, Ltd., Osaka-shi (JP)

(21) Appl. No.: 10/501,791

(22) PCT Filed: Mar. 20, 2003
(86) PCT No.: PCT/JP03/03483

§ 371 Date: Jul. 2, 2004

(30) Foreign Application Priority Data
Oct. 24, 2002 (JP) 2002-309388

(51) Int. Cl. C23C 16/00

(52) U.S. Cl. 118/725

(57) ABSTRACT

For semiconductor manufacturing equipment a ceramic susceptor is made available in which by optimizing the inter-wiring-line separation in the resistive heating element, damage due to shorting between resistive heating element lines during heating operations is prevented while wafer-surface temperature uniformity is maintained. The ceramic susceptor (1) for semiconductor manufacturing equipment has a resistive heating element (3a) on a surface of or inside ceramic substrate (2), with the smallest angle θ formed by the bottom and lateral sides of the resistive heating element (3a) In a section of the resistive heating element (3a) being 5° or greater. A plasma electrode may be arranged on a surface of or inside the ceramic substrates (2a) of the ceramic susceptor (1). The ceramic substrates (2a) are preferably made of at least one selected from aluminum nitride, silicon nitride, aluminum oxynitride, and silicon carbide.

### TECHNICAL FIELD

The present invention relates to ceramic susceptors used to hold and heat wafers in semiconductor manufacturing equipment in which specific processes are carried out on the wafers in the course of semiconductor manufacture.

### BACKGROUND ART

Various structures have been proposed to date for ceramic susceptors used in semiconductor manufacturing equipment. Japanese Examined Pat. App. Pub. No. H06-28258, for example, proposes a semiconductor wafer heating device equipped with a ceramic susceptor that is installed in a reaction chamber and has an embedded resistive heating element, and a pillar-like support member that is provided on the side of the susceptor other than its wafer-heating side and forms a gastight seal between it and the chamber.

In order to reduce manufacturing costs, a transition to wafers of larger diametric span—from 8-inch to 12-inch in outer diameter—is in progress, resulting in the diameter of the ceramic susceptor that holds the wafer increasing to 300 mm or more. At the same time, calls are for wafer-surface temperature deviation—i.e., temperature uniformity—to be within ±1.0%, and preferably within ±0.5%, in a wafer loaded on the ceramic susceptor and being heated by the resistive heating element, to which current is being supplied.

Patent Reference 1

Japanese Examined Pat. App. Pub. No. H06-28258.

The pattern of the resistive heating element formed on the surface of or inside the ceramic susceptor is designed and arranged so as to uniformly heat the surface on which the wafer is supported. More specifically, one conceivable way to improve wafer-surface temperature uniformity would be to arrange the resistive heating element densely by narrowing to the utmost the linewidth of and adjacent inter-line spacing in the resistive heating element.

However, if in laying stress on improving wafer-surface temperature uniformity the spacing of the resistive-heating-element wiring is narrowed too far, a partial discharge phenomenon arises from the potential difference created between wiring lines of the resistive heating element. If this partial discharge phenomenon advances further, shorting occurs between the resistive-heating-element wiring lines, resulting in damage to the ceramic susceptor.

### DISCLOSURE OF INVENTION

An object of the present invention, in view of such circumstances to date, is to optimize the design of the resistive-heating-element pattern and thereby make available for semiconductor manufacturing equipment a ceramic susceptor that while maintaining wafer-surface temperature uniformity makes for preventing susceptor damage due to shorting between resistive heating element lines during heating operations.

To achieve this object the present invention provides, for semiconductor manufacturing equipment, a ceramic susceptor having a resistive heating element on a surface of or inside a ceramic substrate, and characterized by the minimum angle formed by bottom and lateral faces in a section through the resistive heating element being 5° or more.

When a wafer is placed on the wafer support surface of this ceramic susceptor for semiconductor manufacturing equipment and the resistive heating element is energized and heated, variation in the wafer surface temperature is preferably ±1.0% or less, and further preferably ±0.5% or less, at the working temperature.

Furthermore, the ceramic substrates of this ceramic susceptor for semiconductor manufacturing equipment are preferably made from a ceramic selected from at least one of the following materials: aluminum nitride, silicon nitride, aluminum oxynitride, and silicon carbide. Yet further preferably, the ceramic substrates are aluminum nitride or silicon carbide substrates with thermal conductivity of 100 W/m·K or greater.

Furthermore, the resistive heating element of this ceramic susceptor for semiconductor manufacturing equipment is preferably made from at least one metal selected from tungsten, molybdenum, platinum, palladium, silver, nickel, and chrome.

A plasma electrode may further be disposed on a surface of or inside the ceramic substrate of this ceramic susceptor for semiconductor manufacturing equipment.

### BRIEF DESCRIPTION OF DRAWINGS

FIG. 1 is a schematic section diagram of a resistive heating element in a ceramic susceptor, FIG. 1(a) showing an actual resistive heating element in section, and FIG. 1(b) showing an ideal resistive heating element in section;

FIG. 2 is a schematic section diagram of a ceramic susceptor according to a preferred embodiment of the present invention; and

FIG. 3 is a schematic section diagram of a ceramic susceptor according to another embodiment of the present invention.

### BEST MODE FOR CARRYING OUT THE INVENTION

Having studied in detail phenomena in which cracking and like damage occurs in ceramic susceptors when the susceptor temperature is elevated by passing current into its resistive heating element, the present inventors discovered that resistive-heating-element wiring lines that neighbor each other short in regions where their difference in potential is greatest, leading to damage to the susceptor.

To avert this sort of shorting phenomenon in the resistive heating element, the present inventors focused their attention on the sectional form of the resistive heating element, and especially on the angle formed by the bottom and lateral faces in a section through the resistive-heating-element wiring lines (also referred to simply as “resistive-heating-element section” hereinafter). More specifically, whether this shorting phenomenon is present or not is determined by the separation between the wiring lines of the resistive heating element, the applied voltage, the form of the electrodes, and the atmospheric pressure. The inter-line separation is limited by designing the resistive-heating-element pattern to gain temperature uniformity in the susceptor, while the applied voltage and atmospheric pressure are determined by the process conditions.

If the inter-line separation of the resistive heating element is constant, shorting is least likely to occur when the line section is square- or rectangular-shaped, while shorting is most likely to occur when the line section is needle shaped. Based on the thinking that cracks caused by shorting could be prevented by how the sectional form of the susceptor resistive heating element is devised, ways of doing this were investigated.

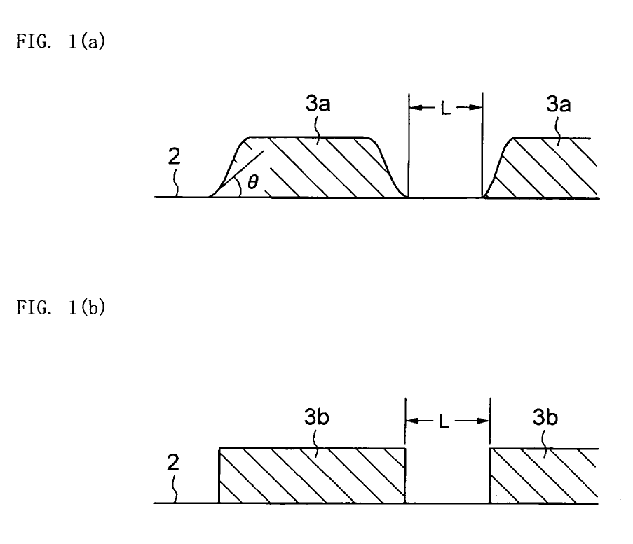

The resistive heating element of a ceramic susceptor is generally formed by printing and firing a conductive paste onto a sintered ceramic compact or green sheet. When the sectional shape of the resulting resistive heating element is shown schematically, it is usually presented with the rectilinear shape of an ideal resistive heating element 3b as shown in FIG. 1(b). In actuality, however, the resistive heating element 3a always has a basically trapezoidal shape with inclined sides as shown in FIG. 1(a), due to sagging or spreading of the conductive paste, and the smallest angle θ formed by the lateral sides and bottom of the resistive heating element 3a contacting the ceramic substrate 2 is acute.

Given these factors, presence/absence of shorting between wiring lines when the resistive heating element is drawing current/heating was investigated by varying the inter-line separation L of the resistive heating element 3a in the resistive heating element section indicated in FIG. 1(b) in a range of 0.5 mm to 20 mm, and meanwhile setting the smallest angle θ formed by the bottom and lateral faces of the resistive heating element larger in stages starting with 2°. As a result, it was found that regardless of the inter-line separation L, shorting between lines can be averted by having the smallest angle θ formed by the bottom and lateral sides in the resistive heating element section be 5° or greater.

Here, to change the smallest angle θ formed by the bottom and lateral sides in the resistive heating element section, a method such as changing the paste dilution to adjust paste viscosity when print-coating the paste for resistive-heating-element formation may be adopted.

In a ceramic susceptor according to the present invention, even with the smallest angle θ formed by the bottom and sides of the resistive heating element being 5° or greater, care that the inter-line separation L of the resistive heating element is not too small, i.e., generally that the inter-line separation L is not less than 0.1 mm, is needed because otherwise shorting between lines is liable to occur.

Using a ceramic susceptor in which the smallest angle θ formed by the bottom and sides in the resistive heating element section is 5° or greater according to the present invention, deviation (i.e., temperature uniformity) in the wafer surface temperature when the resistive heating element is drawing current/heating can be brought advantageously to within ±1.0%, and more advantageously to within ±0.5%, at the working temperature.

If the inter-line separation L of the resistive heating element is too large, however, deviation in the wafer surface temperature when the resistive heating element is drawing current/heating grows greater, making it difficult to achieve desired temperature uniformity. The inter-line separation L of the resistive heating element is therefore preferably 5 mm or less.

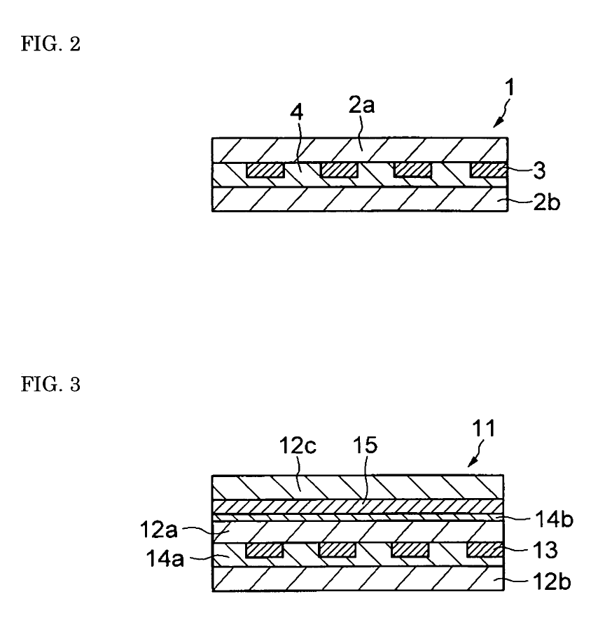

The specific structure of a ceramic susceptor according to the present invention is described next with reference to FIG. 2 and FIG. 3. The ceramic susceptor 1 shown in FIG. 2 has a resistive heating element 3 with a prescribed wiring pattern provided on one surface of a ceramic substrate 2a, and a separate ceramic substrate 2b bonded to the same surface of the ceramic substrate 2a by means of an adhesive layer 4 of glass or ceramic. Here, the linewidth in the wiring pattern of the resistive heating element 3 is preferably rendered to be 5 mm or less, and more preferably 1 mm or less.

The ceramic susceptor 11 shown in FIG. 3 is furnished with an internal resistive heating element 13 and a plasma electrode 15. More specifically, a ceramic substrate 12a having the resistive heating element 13 on one surface thereof and a ceramic substrate 12b are bonded by an adhesive layer 14a similarly as with the ceramic susceptor shown in FIG. 2. At the same time, a separate ceramic substrate 12c provided with a plasma electrode 15 is bonded to the other side of the ceramic substrate 12a by means of a glass or ceramic adhesive layer 14b.

It should be understood that instead of bonding respective ceramic substrates to manufacture the ceramic susceptors, the ceramic susceptors shown in FIG. 2 and FIG. 3 can alternatively be manufactured by preparing approximately 0.5 mm thick green sheets, print-coating a conductive paste in the circuit pattern of the resistive heating element and/or plasma electrode on respective green sheets, laminating these green sheets together with other green sheets as needed to achieve the required thickness, and then simultaneously sintering the multiple green sheets to unite them.

### Embodiments

### Embodiment 1

A sintering additive and a binder were added to, and dispersed into and mixed with, aluminum nitride (AlN) powder using a ball mill. The resulting powder blend was dried with a spray dryer and then press-molded into 1-mm thick, 380-mm diameter disks. The molded disks were degreased in a non-oxidizing atmosphere at a temperature of 800° C., and then sintered for 4 hours at 1900° C., producing sintered AlN compacts. The thermal conductivity of the resulting AlN sinters was 170 W/mK. The circumferential surface of each sintered AlN compact was then polished to an outside diameter of 300 mm to prepare two AlN substrates for a ceramic susceptor.

A paste of tungsten powder and sintering additive kneaded together with a binder was then print-coated on the surface of one of these AlN substrates to form a predetermined pattern for the resistive-heating-element wiring lines. The printing screen and paste viscosity were varied to change in the resistive heating element in section the adjoining inter-line separation L and the smallest angle θ formed by the bottom and lateral sides of the resistive heating element (termed “sectional smallest angle θ” below). The resulting AlN substrate was degreased in a non-oxidizing atmosphere at a temperature of 800° C. and then baked at 1700° C., producing a tungsten resistive heating element.

A paste of Y₂O₃ adhesive agent kneaded with a binder was print-coated on the surface of the remaining AlN substrate, which was then degreased at 500° C. The adhesive layer of this AlN substrate was then overlaid on the side of the AlN substrate on which the resistive heating element was formed, and the substrates were bonded by heating at 800° C. Sample ceramic susceptors having the FIG. 1 configuration and differing in inter-line separation L and sectional smallest angle θ as set forth in the following Table I were thus produced.

The temperature of each sample susceptor produced in this way was then raised to 500° C. by flowing a current at a voltage of 200 V into the resistive heating element through two electrodes formed on the surface of the susceptor opposite the wafer-support side, and the susceptors were checked for presence/absence of cracking occurrences. In addition, a 0.8-mm thick, 300-mm diameter silicon wafer was placed on the wafer-support side of the ceramic susceptor, and the temperature distribution in the wafer surface was measured to find the temperature uniformity at 500° C. The results obtained are set forth for each sample in Table I below.

TABLE I

| | Sectional | Inter-line | Susceptor cracking | Wafer-surface |
|---|---|---|---|---|
| | smallest | separation | occurrence freq. | 500° C. temp. |
| Sample | angle θ (°) | L (mm) | (N = 5) | uniformity (° C.) |
| 1 | 7 | 20 | 0/5 | ±1.80 |
| 2 | 7 | 10 | 0/5 | ±1.31 |
| 3 | 7 | 5 | 0/5 | ±0.48 |
| 4 | 7 | 1 | 0/5 | ±0.40 |
| 5 | 7 | 0.5 | 0/5 | ±0.35 |
| 6 | 5 | 20 | 0/5 | ±1.80 |
| 7 | 5 | 10 | 0/5 | ±1.31 |
| 8 | 5 | 5 | 0/5 | ±0.48 |
| 9 | 5 | 1 | 0/5 | ±0.40 |
| 10 | 5 | 0.5 | 0/5 | ±0.35 |
| 11* | 4 | 20 | 0/5 | ±1.80 |
| 12* | 4 | 10 | 0/5 | ±1.31 |
| 13* | 4 | 5 | 2/5 | ±0.48 |
| 14* | 4 | 1 | 4/5 | ±0.40 |
| 15* | 4 | 0.5 | 5/5 | ±0.35 |
| 16* | 2 | 20 | 0/5 | ±1.80 |
| 17* | 2 | 10 | 2/5 | ±1.31 |
| 18* | 2 | 5 | 4/5 | ±0.48 |
| 19* | 2 | 1 | 4/5 | ±0.40 |
| 20* | 2 | 0.5 | 5/5 | ±0.35 |

Note:
Samples marked with an asterisk (*) in the table are comparative examples.

As will be understood from the results set forth in Table I, susceptor cracking during heating/temperature elevation could be eliminated in an aluminum nitride ceramic susceptor by the sectional smallest angle θ of the resistive heating element being 5° or greater. It is also evident that temperature uniformity of within ±0.5% was achieved by the inter-line separation L of the resistive heating element being within the range 0.5 mm to 5 mm.

### Embodiment 2

A sintering additive and a binder were added to, and dispersed into and mixed with, silicon nitride (Si₃N₄) powder using a ball mill. The resulting powder blend was dried with a spray dryer and then press-molded into 1-mm thick, 380-mm diameter disks. The molded disks were degreased in a non-oxidizing atmosphere at a temperature of 800° C., and then sintered for 4 hours at 1550° C., producing sintered Si₃N₄ compacts. The thermal conductivity of the resulting Si₃N₄ sinters was 20 W/mK. The circumferential surface of each sintered Si₃N₄ compact was then polished to an outside diameter of 300 mm to prepare two Si₃N₄ substrates for a ceramic susceptor.

A paste of tungsten powder and sintering additive kneaded together with a binder was then print-coated on the surface of one of these Si₃N₄ substrates to form a predetermined pattern for the resistive-heating-element wiring lines. The printing screen and paste viscosity were varied to change in the resistive heating element in section the adjoining inter-line separation L and the smallest angle 0. This Si₃N₄ substrate was then degreased in a non-oxidizing atmosphere at a temperature of 800° C. and then baked at 1700° C., producing a tungsten resistive heating element.

A paste of SiO₂ adhesive agent kneaded with binder was print-coated on the surface of the other Si₃N₄ substrate, which was then degreased at 500° C. The adhesive layer of this Si₃N₄ substrate was then overlaid on the side of the Si₃N₄ substrate on which the resistive heating element was formed, and the substrates were bonded by heating at 800° C. Sample ceramic susceptors having the FIG. 1 configuration and differing in inter-line separation L and sectional smallest angle θ as set forth in the following Table II were thus produced.

The temperature of each sample susceptor produced in this way was then raised to 500° C. by flowing a current at a voltage of 200 V into the resistive heating element, and the susceptors were checked for presence/absence of cracking occurrences. In addition, a 0.8-mm thick, 300-mm diameter silicon wafer was placed on the wafer-support side of the ceramic susceptor, and the temperature distribution in the wafer surface was measured to find the temperature uniformity at 500° C. The results obtained are set forth for each sample in Table II below.

TABLE II

| | Sectional | Inter-line | Susceptor cracking | Wafer-surface |
|---|---|---|---|---|
| | smallest | separation | occurrence freq. | 500° C. temp. |
| Sample | angle θ (°) | L (mm) | (N = 5) | uniformity (° C.) |
| 21 | 7 | 20 | 0/5 | ±2.85 |
| 22 | 7 | 10 | 0/5 | ±2.50 |
| 23 | 7 | 5 | 0/5 | ±0.91 |
| 24 | 7 | 1 | 0/5 | ±0.81 |
| 25 | 7 | 0.5 | 0/5 | ±0.67 |
| 26 | 5 | 20 | 0/5 | ±2.85 |
| 27 | 5 | 10 | 0/5 | ±2.50 |
| 28 | 5 | 5 | 0/5 | ±0.91 |
| 29 | 5 | 1 | 0/5 | ±0.81 |
| 30 | 5 | 0.5 | 0/5 | ±0.67 |
| 31* | 4 | 20 | 0/5 | ±2.85 |
| 32* | 4 | 10 | 0/5 | ±2.50 |
| 33* | 4 | 5 | 1/5 | ±0.91 |
| 34* | 4 | 1 | 3/5 | ±0.81 |
| 35* | 4 | 0.5 | 4/5 | ±0.67 |
| 36* | 2 | 20 | 0/5 | ±2.85 |
| 37* | 2 | 10 | 2/5 | ±2.50 |
| 38* | 2 | 5 | 4/5 | ±0.91 |
| 39* | 2 | 1 | 5/5 | ±0.81 |
| 40* | 2 | 0.5 | 5/5 | ±0.67 |

Note:
Samples marked with an asterisk (*) in the table are comparative examples.

As will be understood from Table II, in a silicon nitride ceramic susceptor also, as was likewise the case with the aluminum nitride manufacture of Embodiment 1, susceptor heating/temperature-elevation cracking could be eliminated by the sectional smallest angle θ of the resistive heating element being 5° or greater. Furthermore, temperature uniformity of within ±1.0% was achieved by the inter-line separation L of the resistive heating element being within the range 0.5 mm to 5 mm.

### Embodiment 3

A sintering additive and a binder were added to, and dispersed into and mixed with, aluminum oxynitride (AlON) powder using a ball mill. The resulting powder blend was dried with a spray dryer and then press-molded into 1-mm thick, 380-mm diameter disks. The molded disks were degreased in a non-oxidizing atmosphere at a temperature of 800° C., and then sintered for 4 hours at 1770° C., producing sintered AlON compacts. The thermal conductivity of the resulting AlON sinters was 20 W/mK. The circumferential surface of each sintered AlON compact was then polished to an outside diameter of 300 mm to prepare two AlON substrates for a ceramic susceptor.

A paste of tungsten powder and sintering additive kneaded together with a binder was then print-coated on the surface of one of these AlON substrates to form a predetermined pattern for the resistive-heating-element wiring lines. The printing screen and paste viscosity were varied to change in the resistive heating element in section the adjoining inter-line separation L and the smallest angle θ. This AlON substrate was then degreased in a non-oxidizing atmosphere at a temperature of 800° C. and then baked at 1700° C., producing a tungsten resistive heating element.

A paste of SiO₂ adhesive agent kneaded with a binder was print-coated on the surface of the other AlON substrate, which was then degreased at 500° C. The adhesive layer of this AlON substrate was then overlaid on the side of the AlON substrate on which the resistive heating element was formed, and the substrates were bonded by heating at 800° C. Sample ceramic susceptors having the FIG. 1 configuration and differing in inter-line separation L and sectional smallest angle θ as set forth in the following Table III were thus produced.

The temperature of each sample susceptor produced in this way was then raised to 500° C. by flowing a current at a voltage of 200 V into the resistive heating element, and the susceptors were checked for presence/absence of cracking occurrences. In addition, a 0.8-mm thick, 300-mm diameter silicon wafer was placed on the wafer-support side of the ceramic susceptor, and the temperature distribution in the wafer surface was measured to find the temperature uniformity at 500° C. The results obtained are set forth for each sample in Table III below.

TABLE III

| | Sectional | Inter-line | Susceptor cracking | Wafer-surface |
|---|---|---|---|---|
| | smallest | separation | occurrence freq. | 500° C. temp. |
| Sample | angle θ (°) | L (mm) | (N = 5) | uniformity (° C.) |
| 41 | 7 | 20 | 0/5 | ±2.85 |
| 42 | 7 | 10 | 0/5 | ±2.50 |
| 43 | 7 | 5 | 0/5 | ±0.91 |
| 44 | 7 | 1 | 0/5 | ±0.81 |
| 45 | 7 | 0.5 | 0/5 | ±0.67 |
| 46 | 5 | 20 | 0/5 | ±2.85 |
| 47 | 5 | 10 | 0/5 | ±2.50 |
| 48 | 5 | 5 | 0/5 | ±0.91 |
| 49 | 5 | 1 | 0/5 | ±0.81 |
| 50 | 5 | 0.5 | 0/5 | ±0.67 |
| 51* | 4 | 20 | 0/5 | ±2.85 |
| 52* | 4 | 10 | 0/5 | ±2.50 |
| 53* | 4 | 5 | 3/5 | ±0.91 |
| 54* | 4 | 1 | 4/5 | ±0.81 |
| 55* | 4 | 0.5 | 5/5 | ±0.67 |
| 56* | 2 | 20 | 0/5 | ±2.85 |
| 57* | 2 | 10 | 2/5 | ±2.50 |
| 58* | 2 | 5 | 4/5 | ±0.91 |
| 59* | 2 | 1 | 5/5 | ±0.81 |
| 60* | 2 | 0.5 | 5/5 | ±0.67 |

Note:
Samples marked with an asterisk (*) in the table are comparative examples.

As will be understood from Table III, in an aluminum oxynitride ceramic susceptor also, as was likewise the case with the aluminum nitride manufacture of Embodiment 1, susceptor heating/temperature-elevation cracking could be eliminated by the sectional smallest angle θ of the resistive heating element being 5° or greater. Furthermore, temperature uniformity of within ±1.0% was achieved by the inter-line separation L of the resistive heating element being within the range 0.5 mm to 5 mm.

### Embodiment 4

Pairs of AlN substrates for a ceramic susceptor with a 300 mm outside diameter were prepared from an aluminum nitride sinter using the same method described in Embodiment 1. When sample ceramic susceptors were made using these AlN substrate pairs, other than changing the material of the resistive heating element formed on the surface of one AlN substrate to Mo, to Pt, to Ag—Pd, and to Ni—Cr, W resistive heating elements differing in inter-line separation Land sectional smallest angle θ were formed in the same way as in Embodiment 1.

A SiO₂ glass bonding agent was then coated over the surface of the remaining AlN substrate in each pair, and degreased in a non-oxidizing atmosphere at 800° C. The adhesive glass layer of this AlN substrate was then overlaid on the side of the other AlN substrate on which the resistive heating element was formed, and the substrate pairs were bonded by heating at 800° C., thereby producing ceramic susceptors of AlN differing in inter-line separation L and sectional smallest angle θ as set forth in the following Table IV.

The temperature of each sample susceptor produced in this way was then raised to 500° C. by flowing a current at a voltage of 200 V into the resistive heating element, and the susceptors were checked for presence/absence of cracking occurrences. In addition, a 0.8-mm thick, 300-mm diameter silicon wafer was placed on the wafer-support side of the ceramic susceptor, and the temperature distribution in the wafer surface was measured to find the temperature uniformity at 500° C. The results obtained are set forth for each sample in Table IV below.

TABLE IV

| | | | | Susceptor | Wafer-surface |
|---|---|---|---|---|---|
| | | Sectional | Inter-line | cracking | 500° C. temp. |
| | Heating | smallest | separation | occurrence | uniformity |
| Sample | element | angle θ (°) | L (mm) | freq. (N = 5) | (° C.) |
| 61 | Mo | 7 | 10 | 0/5 | ±1.28 |
| 62 | Mo | 7 | 0.5 | 0/5 | ±0.35 |
| 63 | Mo | 5 | 10 | 0/5 | ±1.28 |
| 64 | Mo | 5 | 5 | 0/5 | ±0.45 |
| 65 | Mo | 5 | 1 | 0/5 | ±0.37 |
| 66 | Mo | 5 | 0.5 | 0/5 | ±0.35 |
| 67* | Mo | 4 | 10 | 0/5 | ±1.28 |
| 68* | Mo | 4 | 1 | 2/5 | ±0.37 |
| 69* | Mo | 4 | 0.5 | 5/5 | ±0.35 |
| 70 | Pt | 7 | 10 | 0/5 | ±1.28 |
| 71 | Pt | 7 | 0.5 | 0/5 | ±0.35 |
| 72 | Pt | 5 | 10 | 0/5 | ±1.28 |
| 73 | Pt | 5 | 5 | 0/5 | ±0.45 |
| 74 | Pt | 5 | 1 | 0/5 | ±0.37 |
| 75 | Pt | 5 | 0.5 | 0/5 | ±0.35 |
| 76* | Pt | 4 | 10 | 0/5 | ±1.28 |
| 77* | Pt | 4 | 1 | 4/5 | ±0.37 |
| 78* | Pt | 4 | 0.5 | 4/5 | ±0.35 |
| 79 | Ag—Pd | 7 | 10 | 0/5 | ±1.28 |
| 80 | Ag—Pd | 7 | 0.5 | 0/5 | ±0.35 |
| 81 | Ag—Pd | 5 | 10 | 0/5 | ±1.28 |
| 82 | Ag—Pd | 5 | 5 | 0/5 | ±0.45 |
| 83 | Ag—Pd | 5 | 1 | 0/5 | ±0.37 |
| 84 | Ag—Pd | 5 | 0.5 | 0/5 | ±0.35 |
| 85* | Ag—Pd | 4 | 10 | 0/5 | ±1.28 |
| 86* | Ag—Pd | 4 | 1 | 3/5 | ±0.37 |
| 87* | Ag—Pd | 4 | 0.5 | 4/5 | ±0.35 |
| 88 | Ni—Cr | 7 | 10 | 0/5 | ±1.28 |
| 89 | Ni—Cr | 7 | 0.5 | 0/5 | ±0.35 |
| 90 | Ni—Cr | 5 | 10 | 0/5 | ±1.28 |
| 91 | Ni—Cr | 5 | 5 | 0/5 | ±0.45 |
| 92 | Ni—Cr | 5 | 1 | 0/5 | ±0.37 |
| 93 | Ni—Cr | 5 | 0.5 | 0/5 | ±0.35 |
| 94* | Ni—Cr | 4 | 10 | 0/5 | ±1.28 |
| 95* | Ni—Cr | 4 | 1 | 3/5 | ±0.37 |
| 96* | Ni—Cr | 4 | 0.5 | 5/5 | ±0.35 |

Note:
Samples marked with an asterisk (*) in the table are comparative examples.

As will be understood from Table IV, also in an aluminum oxynitride ceramic susceptor having a resistive heating element made of Mo, Pt, Ag—Pd, or Ni—Cr, as was likewise the case with the tungsten resistive heating elements set forth in Embodiment 1, susceptor heating/temperature-elevation cracking could be eliminated by the sectional smallest angle θ of the resistive heating element being 50 or greater. Furthermore, temperature uniformity of within ±0.5% was achieved by the inter-line separation L of the resistive heating element being within the range 0.5 mm to 5 mm.

### Embodiment 5

A sintering additive, a binder, a dispersing agent and alcohol were added to an aluminum nitride (AlN) powder and kneaded into a paste, which was then formed using a doctor blade technique into green sheets approximately 0.5 mm thick.

Next the green sheets were dried for 5 hours at 80° C. A paste of tungsten powder and sintering additive kneaded together with a binder was then print-coated on the surface of single plies of the green sheets to form a resistive-heating-element layer in a predetermined circuit pattern. The printing screen and paste viscosity were varied to change in the resistive heating element in section the adjoining inter-line separation L and the smallest angle θ.

Second plies of the green sheets were likewise dried and the same tungsten paste was print-coated onto a surface thereof to form a plasma electrode layer. These two plies of green sheets each having a conductive layer were then laminated in a total 50 plies with green sheets that were not printed with a conductive layer, and the laminates were united by heating them at a temperature of 140° C. while applying pressure of 70 kg/cm².

The resulting laminates were degreased for 5 hours at 600° C. in a non-oxidizing atmosphere, then hot-pressed at 1800° C. while applying pressure of 100 to 150 kg/cm², thereby producing 3 mm thick AlN plates. These plates were then cut to form 380-mm diameter disks, and the periphery of each disk was polished to a 300 mm diameter. Sample ceramic susceptors having the FIG. 2 configuration internal featuring a tungsten resistive heating element and plasma electrode and differing in inter-line separation L and sectional smallest angle θ as set forth in the following Table V were thus produced.

The temperature of each sample susceptor produced in this way was then raised to 500° C. by flowing a current at a voltage of 200 V into the resistive heating element, and the susceptors were checked for presence/absence of cracking occurrences. In addition, a 0.8-mm thick, 300-mm diameter silicon wafer was placed on the wafer-support side of the ceramic susceptor, and the temperature distribution in the wafer surface was measured to find the temperature uniformity at 500° C. The results obtained are set forth for each sample in Table V below.

TABLE V

| | Sectional | Inter-line | Susceptor cracking | Wafer-surface |
|---|---|---|---|---|
| | smallest | separation | occurrence freq. | 500° C. temp. |
| Sample | angle θ (°) | L (mm) | (N = 5) | uniformity (° C.) |
| 97 | 7 | 20 | 0/5 | ±1.86 |
| 98 | 7 | 10 | 0/5 | ±1.29 |
| 99 | 7 | 5 | 0/5 | ±0.47 |
| 100 | 7 | 1 | 0/5 | ±0.41 |
| 101 | 7 | 0.5 | 0/5 | ±0.36 |
| 102 | 5 | 20 | 0/5 | ±1.86 |
| 103 | 5 | 10 | 0/5 | ±1.29 |
| 104 | 5 | 5 | 0/5 | ±0.47 |
| 105 | 5 | 1 | 0/5 | ±0.41 |
| 106 | 5 | 0.5 | 0/5 | ±0.36 |
| 107 | 4 | 20 | 0/5 | ±1.86 |
| 108 | 4 | 10 | 0/5 | ±1.29 |
| 109 | 4 | 5 | 4/5 | ±0.47 |
| 110 | 4 | 1 | 4/5 | ±0.41 |
| 111 | 4 | 0.5 | 4/5 | ±0.36 |
| 112 | 2 | 20 | 0/5 | ±1.86 |
| 113 | 2 | 10 | 0/5 | ±1.29 |
| 114 | 2 | 5 | 4/5 | ±0.47 |
| 115 | 2 | 1 | 5/5 | ±0.41 |
| 116 | 2 | 0.5 | 5/5 | ±0.36 |

As will be understood from the results shown in Table V, even with aluminum nitride ceramic susceptors having both an internal resistive heating element and a plasma electrode, susceptor heating/temperature-elevation cracking could be eliminated by the sectional smallest angle θ of the resistive heating element being 5° or greater. Furthermore, temperature uniformity of within ±0.5% was achieved by the inter-line separation L of the resistive heating element being within the range 0.5 mm to 5 mm.

### INDUSTRIAL APPLICABILITY

In accordance with the present invention, optimizing the angle between the bottom and lateral faces of the resistive heating element in section makes available for semiconductor manufacturing equipment a ceramic susceptor in which, while wafer-surface temperature uniformity is maintained, there is no susceptor damage due to shorting between resistive heating element lines during heating operations.

1. For semiconductor manufacturing equipment, a ceramic susceptor comprising:
a ceramic substrate defining a wafer-support side, and
a resistive heating element composed of wiring lines, defining bottom and lateral sides, in a predetermined configuration provided on either a surface of or inside a said ceramic substrate, said resistive heating element being configured so that in section through said wiring lines the smallest angle formed by the bottom and lateral sides is 5° or greater.

2. A ceramic susceptor as set forth in claim 1, wherein when a wafer is placed on the wafer support side and said resistive heating element is drawing current and heated deviation in the wafer surface temperature is ±1.0% or less at working temperature.

3. A ceramic susceptor as set forth in claim 2, wherein deviation in the wafer surface temperature is within ±0.5% at working temperature.

4. A ceramic susceptor as set forth in claim 1, wherein said ceramic substrate is made of at least one ceramic selected from aluminum nitride, silicon nitride, aluminum oxynitride and silicon carbide.

5. A ceramic susceptor as set forth in claim 1 wherein said ceramic substrate is either aluminum nitride or silicon carbide of 100 W/m·K or greater thermal conductivity.

6. A ceramic susceptor as set forth in claim 1, wherein said resistive heating element is made from at least one metal selected from tungsten, molybdenum, platinum, palladium, silver, nickel and chrome.

7. A ceramic susceptor as set forth in any claim 1, further comprising a plasma electrode is disposed either on a surface of or inside said ceramic substrate.

8. A ceramic susceptor as set forth in claim 2, wherein said ceramic substrate is made of at least one ceramic selected from aluminum nitride, silicon nitride, aluminum oxynitride and silicon carbide.

9. A ceramic susceptor as set forth in claim 3, wherein said ceramic substrate is made of at least one ceramic selected from aluminum nitride, silicon nitride, aluminum oxynitride and silicon carbide.

10. A ceramic susceptor as set forth in claim 9, wherein said ceramic substrate is either aluminum nitride or silicon carbide of 100 W/m·K or greater thermal conductivity.

11. A ceramic susceptor as set forth in claim 10, wherein said resistive heating element is made from at least one metal selected from tungsten, molybdenum, platinum, palladium, silver, nickel and chrome.

12. A ceramic susceptor as set forth in any claim 2, further comprising a plasma electrode disposed either on a surface of or inside said ceramic substrate.

13. A ceramic susceptor as set forth in any claim 4, further comprising a plasma electrode disposed either on a surface of or inside said ceramic substrate.

14. A ceramic susceptor as set forth in any claim 11, further comprising a plasma electrode disposed either on a surface of or inside said ceramic substrate.
